(19) United States
(12) Patent Application Publication
(10) Pub. No.: US 2012/0031658 A1
(43) Pub. Date: Feb. 9, 2012

(54) PRINTED CIRCUIT BOARD AND METHOD FOR MANUFACTURING THE SAME

(75) Inventors: Jun-Hyung SON, Daejeon (KR); Young-Il Cho, Daejeon (KR); Jo-Youn Won, Seoul (KR)

(73) Assignee: SAMSUNG ELECTRO-MECHANICS CO., LTD.

(21) Appl. No.: 12/985,963

(22) Filed: Jan. 6, 2011

(30) Foreign Application Priority Data
Aug. 9, 2010 (KR) 10-2010-0076611

(51) Int. Cl. H05K 1/11; H05K 3/10

(52) U.S. Cl. 174/261; 29/846

(57) ABSTRACT

A printed circuit board and a method for manufacturing a printed circuit board are disclosed. The printed circuit board in accordance with an embodiment of the present invention includes: a substrate; a first pad and a second pad, formed on one surface of the substrate and separated from each other; a first wiring extended from the first pad; a second wiring extended from the second pad and neighboring the first wiring; and a solder resist layer formed on one surface of the substrate so as to cover portions of the first wiring and the second wiring, and an indentation is formed in an area between the first wiring and the second wiring on one side of the solder resist layer.

### CROSS-REFERENCE TO RELATED APPLICATIONS

This application claims the benefit of Korean Patent Application No. 10-2010-0076611, filed with the Korean Intellectual Property Office on Aug. 9, 2010, the disclosure of which is incorporated herein by reference in its entirety.

### BACKGROUND

1. Technical Field

The present invention is related to a printed circuit board and a method for manufacturing the printed circuit board.

2. Background Art

A printed circuit board includes a substrate, on which a circuit pattern is formed, and a solder resist, which cover the circuit pattern. A portion of the solder resist is opened so as to have a signal connection with a semiconductor chip, and the opened portion is processed through gold plating or other methods. Here, the portion of the circuit pattern where the solder resist is opened and the semiconductor chip is mounted is called a “pad.”

The pad is wire-bonded through an assembly process in order to make the signal connection with the semiconductor chip, but there are difficulties and limits to arranging and attaching the wire on a plurality of pads precisely. It is also possible that an error in manufacturing misaligns the opening of the solder resist that covers the pad, resulting in narrowing of the opening area of the pad and creating an opening not only in the pad but also between the pads by opening an external side of the pad.

Used for the method for mounting the semiconductor chip on the printed circuit board is gold wire, for which the surface of the pad of the printed circuit board needs to be gold-plated.

The method of gold plating includes electrolytic gold plating and electroless gold plating. When the electroless gold plating is used, a step height is formed between the substrate and the solder resist because the solder resist that is opened between the pads is formed on the outside of the substrate. Accordingly, a plating activator and a plating solution that remain on the outside of the pad when the pad is plated react to each other, causing a smearing phenomenon along an interface of the solder resist between the pads and resulting in a defect of short or leak due to an abnormal plating.

### SUMMARY

The present invention provides a printed circuit board and a method for manufacturing the printed circuit board that can additionally secure a distance between pads in which plating is grown.

An aspect of the present invention features a printed circuit board. The printed circuit board in accordance with an embodiment of the present invention can include: a substrate; a first pad and a second pad, formed on one surface of the substrate and separated from each other; a first wiring extended from the first pad; a second wiring extended from the second pad and neighboring the first wiring; and a solder resist layer formed on one surface of the substrate so as to cover portions of the first wiring and the second wiring. In the printed circuit board, an indentation is formed in an area between the first wiring and the second wiring on one side of the solder resist layer.

Another aspect of the present invention features a method for manufacturing a printed circuit board. The method for manufacturing a printed circuit board in accordance with an embodiment of the present invention can include: preparing a substrate, the substrate formed with a first pad and a second pad on one surface thereof, the substrate including a first wiring extended from the first pad and a second wiring extended from the second pad and neighboring the first wiring; and forming a solder resist layer on one surface of the substrate so as to cover portions of the first wiring and the second wiring, wherein an indentation is formed in an area between the first wiring and the second wiring on one side of the solder resist layer.

The indentation can be protruded between the pads.

The indentation can be dented in between the pads.

The indentation can formed in the shape of any one of the letters “V,” “U” and “W.”

After the solder resist layer is formed, the first pad and the second pad can be electroless-plated.

The forming of the solder resist layer can include: covering a solder resist on an entire surface of the substrate; and removing a portion of the solder resist in such a way that portions of the first wiring and the second wiring are covered.

### BRIEF DESCRIPTION OF THE DRAWINGS

FIG. 1 is a flow diagram illustrating a method for manufacturing a printed circuit board in accordance with an embodiment of the printed circuit board.

FIG. 2 illustrates a substrate prepared during a manufacturing process of a printed circuit board in accordance with an embodiment of the present invention.

FIG. 3 illustrates a solder resist layer formed during a manufacturing process of a printed circuit board in accordance with an embodiment of the present invention.

FIG. 4 illustrates a portion of the solder resist layer being removed during a manufacturing process of the printed circuit board in accordance with an embodiment of the present invention.

FIGS. 5 to 11 illustrate printed circuit boards in accordance with other embodiments of the present invention.

### DETAILED DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the ideas and scope of the present invention. Throughout the description of the present invention, when describing a certain technology is determined to evade the point of the present invention, the pertinent detailed description will be omitted.

Terms such as “first” and “second” can be used in describing various elements, but the above elements shall not be restricted to the above terms. The above terms are used only to distinguish one element from the other.

The terms used in the description are intended to describe certain embodiments only, and shall by no means restrict the present invention. Unless clearly used otherwise, expressions in a singular form include a meaning of a plural form. In the present description, an expression such as “comprising” or “including” is intended to designate a characteristic, a number, a step, an operation, an element, a part or combinations thereof, and shall not be construed to preclude any presence or possibility of one or more other characteristics, numbers, steps, operations, elements, parts or combinations thereof.

Hereinafter, some embodiments of a printed circuit board and a method for manufacturing the printed circuit board according to the present invention will be described in detail with reference to the accompanying drawings. Identical or corresponding elements will be given the same reference numerals, regardless of the figure number, and any redundant description of the identical or corresponding elements will not be repeated.

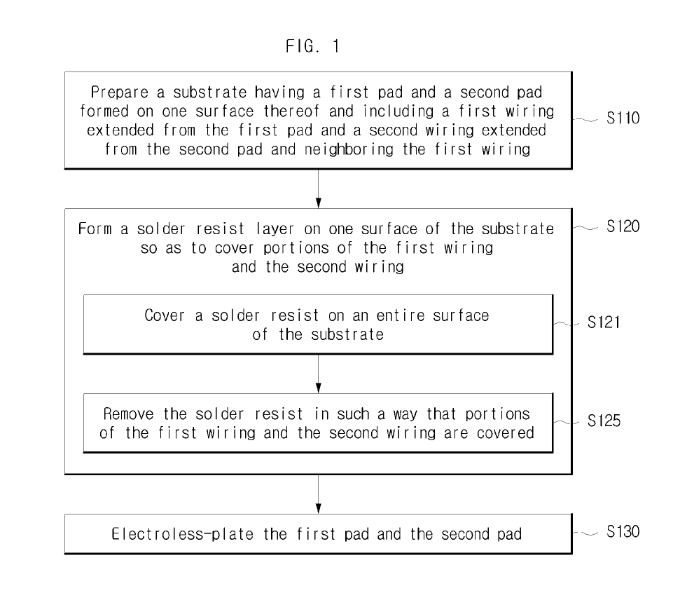

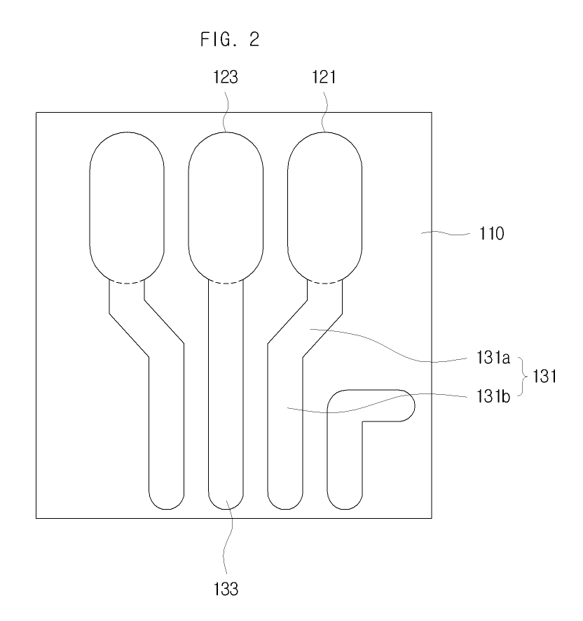

FIG. 1 is a flow diagram illustrating a method for manufacturing a printed circuit board in accordance with an embodiment of the present invention, and FIGS. 2 to 4 illustrate each respective step of the process taken in the method for manufacturing a printed circuit board in accordance with an embodiment of the present invention.

Illustrated in FIGS. 1 to 4 are a printed circuit board 100, a substrate 110, a first pad 121, a second pad 123, a first wiring 131, a second wiring 133, a solder resist 140, a solder resist layer 141 and an indentation 145.

Firstly, as illustrated in FIG. 2, the substrate 110 is prepared (S110). The substrate 110 is formed with the first pad 121 and the second pad 123 on one surface thereof, and includes the first wiring 131, which is extended from the first pad 121, and the second wiring 133, which is extended from the second pad 123 and is neighboring the first wiring 131.

Here, the first wiring 131 can include a bent portion 131a, which is extended from the first pad 121 and bent to approach the second wiring 133, and a parallel portion 131b, which is extended from the bent portion 131a and formed to be parallel with the second wiring 133. Since the bent portion 131a is bent toward the second wiring 133 so that the parallel portion 131b, which is an end portion of the first wiring 131, approaches the second wiring 133, the space between the first wiring 131 and the second wiring 133 can be reduced and the density of the wiring circuit can be increased.

The first pad 121 and the second pad 123 are elements for wire bonding with another printed circuit board or semiconductor chip, and are generally referred to as wire bonding pads or bonding fingers.

The first wiring 131 and the second wiring 133 can be formed by an etching method. For example, the substrate 110 can be coated with dry film and exposed and developed, and then a copper film (not shown) can be etched. In another example, seed layers can be formed on either surface of the substrate 110 through electroless plating, and then the first wiring 131 and the second wiring 133 can be formed through selective electrolytic plating. There can be many other ways to form the first wiring 131 and the second wiring 133. The first pad 121 and the second pad 123 can be formed in the same method as the first wiring 131 and the second wiring 133. The first wiring 131, the second wiring 133, the first pad 121 and the second pad 123 can be formed simultaneously through the same fabrication process.

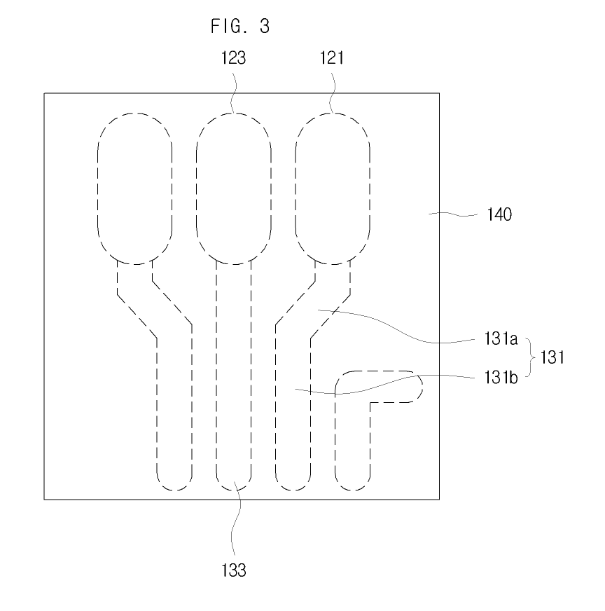

Then, as illustrated in FIG. 3, for example, the entire surface of the substrate 110 is covered with the solder resist 140 (S121). For this, a semi curable material of the solder resist 140 can be laminated on the substrate 110.

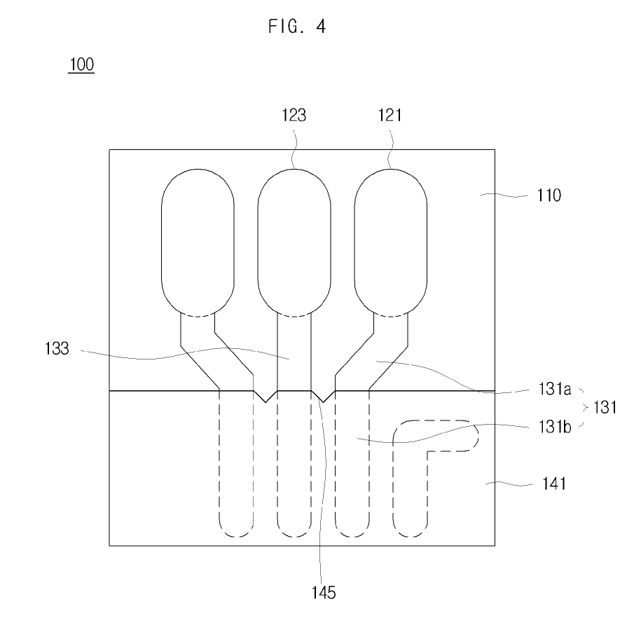

Then, as illustrated in FIG. 4, the solder resist 140 is removed so that portions of the first wiring 131 and the second wiring 133 are exposed (S125). The solder resist 140 can be removed by placing a mask (not shown) over an area of the solder resist 140 and irradiating, for example, ultraviolet rays to expose the solder resist 140 and then by developing an unexposed area of the solder resist 140 by use of a developing solution. Here, the indentation 145 can be formed by deforming the shape of the mask to correspond to the shape of the indentation 145.

As such, the solder resist layer 141 is formed on one surface of the substrate in such a way portions of the first wiring 131 and the second wiring 133 are covered (S120). Here, the indentation 145 is formed in a section of one side of the solder resist layer 141 between the first wiring 131 and the second wiring 133.

The reason why the opened portions include not only the first pad 121 and the second pad 123, which are plated, but also surrounding areas in which the first and second wirings 131, 133 and the first and second pads 121, 123 are connected is to overcome the difficulty of precisely attaching the first pad 121 and the second pad 123 by individually arranging the wire-bonding for each of the first pad 121 and the second pad 123 during the assembly process.

The indentation 145 formed in the solder resist layer 141 can be sharply dented in between the first wiring 131 and the second wiring 133. That is, the indentation 145 can be sharply dented in a horizontal direction of the substrate 110. The indentation 145 can be formed with a plurality of straight lines, for example, in the shape of the letter “V.”

One side of the solder resist layer 141 including the indentation 145 is dented between the first wiring 131 and the second wiring 133 so that, in case an electroless plating is performed on the printed circuit board 100 with the solder resist layer 141 formed thereon, the distance the plating is grown and attached becomes longer than a typical printed circuit board, reducing the occurrence of short or leak between the first wiring 131 and the second wiring 133. In other words, as a gap between the first wiring 131 and the second wiring 133 on one side of the solder resist layer 141 is changed, an additional distance in which the plating is grown can be secured even if the plating is grown in other areas than the first wiring 131 and the second wiring 133 during a chemical plating, thereby reducing the chance of the plating growing and attaching between the first wiring 131 and the second wiring 133.

Then, the first pad 121 and the second pad 123 are electroless-plated (S130). Electroless plating prevents oxidation and increases the bonding between the first and second pads 121, 123 and wires. The electroless plating can be performed by using the ENIG (electroless nickel immersion gold) method, the ENEPIG (electroless nickel electroless palladium immersion gold) method, in which a gold plated film is formed in between an electroless nickel plated film and an electroless palladium plated film, or any of various other methods.

Hitherto, a method for manufacturing a printed circuit board has been described in accordance with an aspect of the present invention. Hereinafter, the structure of the printed circuit board 100 in accordance with another aspect of the present invention will be described.

The structure of the printed circuit board 100 will be described with reference to FIG. 4. Here, any redundant description of the same elements having the same functions as in the method for manufacturing a printed circuit board described above will be omitted.

The first pad 121 and the second pad 123 are formed on one surface of the substrate 110 in such a way that the first pad 121 and the second pad 123 are separated from each other. Also formed on one surface of the substrate 110 are the first wiring, which is extended from the first pad 121, and the second wiring, which is extended from the second pad and neighbors the first wiring 131.

The solder resist layer 141 is formed on one surface of the substrate 110 so as to cover portions of the first wiring 131 and the second wiring 133. The solder resist layer 141 includes the indentation 145 that is dented in between the first wiring 131 and the second wiring 133.

The indentation 145 can be sharply dented in between the first wiring 131 and the second wiring 133. The indentation 145 can be formed by deforming the shape of a mask used for an exposure process. The indentation 145 can be formed with a plurality of straight lines, for example, in the shape of the letter “V.”

In the printed circuit board in accordance with the present embodiment, one side of the solder resist layer 141 is dented between the first wiring 131 and the second wiring 133 so that, in case an electroless plating is performed on the printed circuit board 100 with the solder resist layer 141 formed thereon, the distance the plating is grown and attached becomes longer than a typical printed circuit board, reducing the occurrence of short or leak between the first wiring 131 and the second wiring 133. In other words, as an interface of the solder resist 140 is changed, an additional distance in which the plating is grown can be secured even if the plating is grown in other areas than the first wiring 131 and the second wiring 133 during a chemical plating, thereby reducing the chance of the plating growing and attaching between the first wiring 131 and the second wiring 133.

It has been described with reference to FIGS. 1 to 4 that the indentation 145 in accordance with an embodiment of the present invention is dented in and has straight lines. However, this is only one embodiment for the convenience of description and understanding of the invention, and the present invention shall not be restricted to this embodiment. Some of the other embodiments are described below.

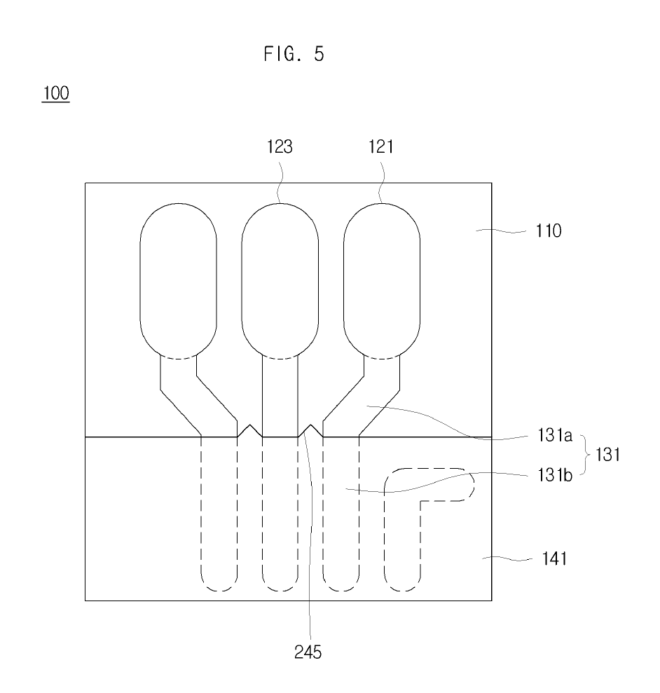

FIGS. 5 to 11 are printed circuit board in accordance with other embodiments of the present invention.

Other embodiments will be described with reference to FIGS. 5 to 11, and any redundant description of the same elements having the same functions as in the embodiment described above will be omitted.

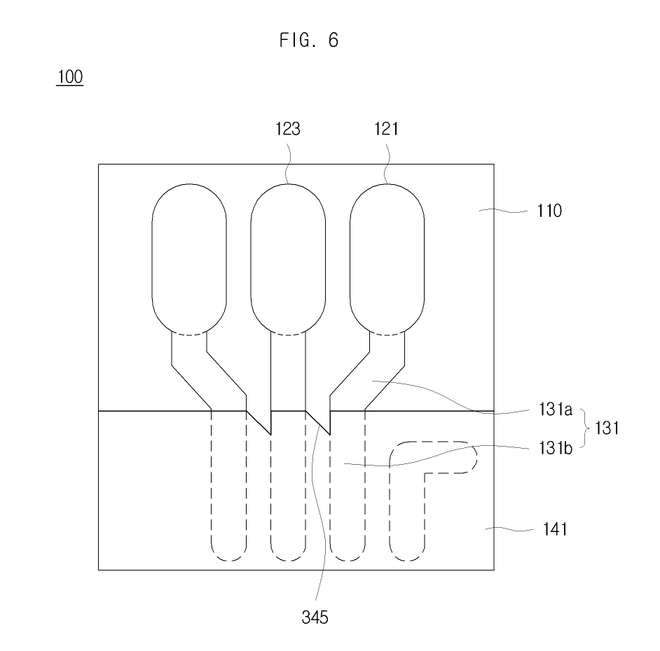

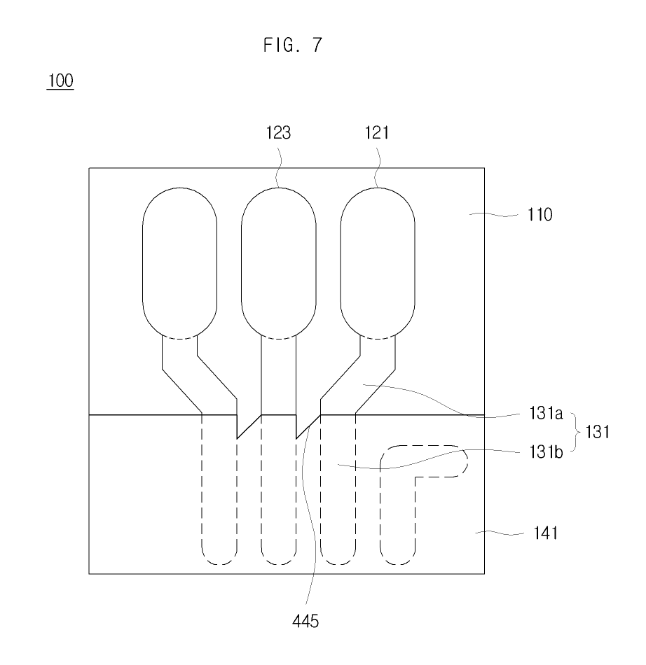

As illustrated in FIG. 5, an indentation 245 can be formed with a plurality of straight lines and can be protruded between the first wiring 131 and the second wiring 133. As illustrated in FIGS. 6 and 7, an indentation 345, 445 can be dented in the shape of a straight line that is slanted to one side.

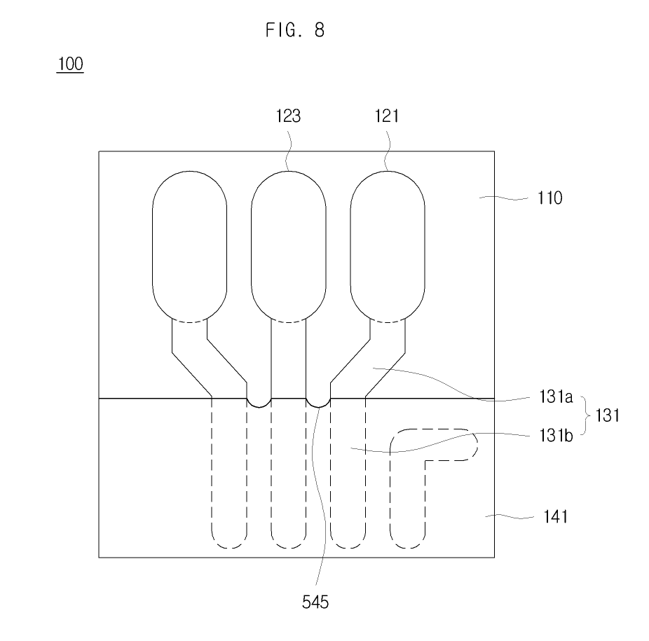

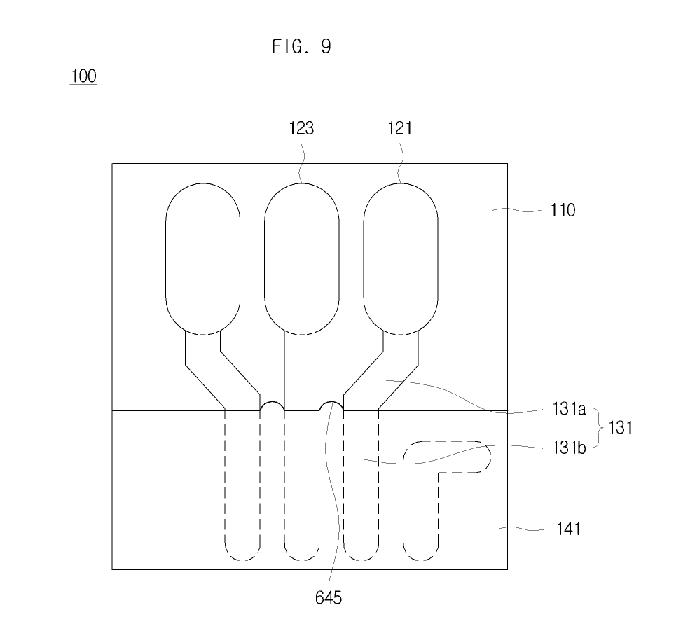

Moreover, as illustrated in FIG. 8, an indentation can be formed with a curved line that is dented in, for example in the shape of the letter “U.” As illustrated in FIG. 9, an indentation 645 can be formed with a curved line that is bulged out.

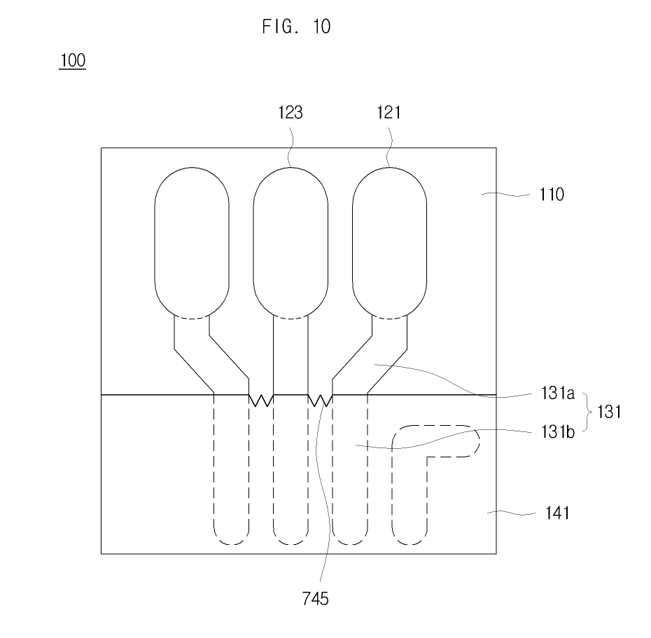

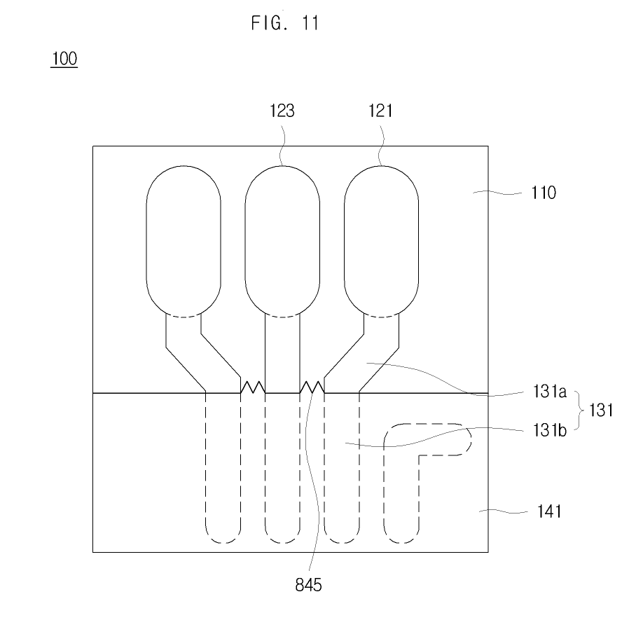

Furthermore, as illustrated in FIG. 10, an indentation 745 can be dented in the shape of the letter “W,” and as illustrated in FIG. 11, an indentation 845 can be bulged out in the shape of the letter “W.” There can be other various modifications of the indentation.

A semiconductor chip can be mounted in the printed circuit board in accordance with the embodiments of the printed circuit board through an assembly process.

The printed circuit board in accordance with an embodiment of the present invention can secure an additional distance in which the plating is grown between the pads, when the pads are electroless-plated in a process of manufacturing the printed circuit board, and thus the chance of short or leak occurred between the pads due to the plating grown between the pads can be reduced.

Although certain embodiments of the present invention have been described, it shall be appreciated by anyone ordinarily skilled in the art to which the present invention pertains that there can be a variety of permutations and modifications of the present invention without departing from the technical ideas and scopes of the present invention that are disclosed in the claims appended below.

A large number of embodiments in addition to the above-described embodiments are present within the claims of the present invention.

What is claimed is:

1. A printed circuit board, comprising:
a substrate;
a first pad and a second pad, formed on one surface of the substrate and separated from each other;
a first wiring extended from the first pad;
a second wiring extended from the second pad and neighboring the first wiring; and
a solder resist layer formed on one surface of the substrate so as to cover portions of the first wiring and the second wiring,
wherein an indentation is formed in an area between the first wiring and the second wiring on one side of the solder resist layer.

2. The printed circuit board of claim 1, wherein the indentation is protruded between the pads.

3. The printed circuit board of claim 1, wherein the indentation is dented in between the pads.

4. The printed circuit board of claim 1, wherein the indentation is formed in the shape of any one of the letters “V,” “U” and “W.”

5. A method for manufacturing a printed circuit board, comprising:
preparing a substrate, the substrate formed with a first pad and a second pad on one surface thereof, the substrate including a first wiring extended from the first pad and a second wiring extended from the second pad and neighboring the first wiring; and
forming a solder resist layer on one surface of the substrate so as to cover portions of the first wiring and the second wiring, wherein an indentation is formed in an area between the first wiring and the second wiring on one side of the solder resist layer.

6. The method of claim 5, wherein the indentation is protruded between the pads.

7. The method of claim 1, wherein the indentation is dented in between the pads.

8. The method of claim 6 or 7, wherein the indentation is formed in the shape of any one of the letters “V,” “U” and “W.”

9. The method of claim 5, wherein, after the forming of the solder resist layer, the first pad and the second pad are electroless-plated.

10. The method of claim 5, wherein the forming of the solder resist layer comprises:
covering a solder resist on an entire surface of the substrate; and
removing a portion of the solder resist in such a way that portions of the first wiring and the second wiring are covered.
